(19) United States
(12) Patent Application Publication
(10) Pub. No.: US 2006/0017149 A1
(43) Pub. Date: Jan. 26, 2006

(54) Substrate-based BGA package, in particular FBGA package

(76) Inventors: Martin Reiss, Dresden (DE); Anton Legen, Muenchen (DE); Steffen Kroehnert, Dresden (DE)

Correspondence Address: SLATER & MATSIL LLP, 17950 PRESTON ROAD, SUITE 1000, DALLAS, TX, 75252, US

(21) Appl. No.: 11/155,332

(22) Filed: Jun. 17, 2005

(30) Foreign Application Priority Data
Jun. 18, 2004 (DE) 10 2004 029 587.5

(51) Int. Cl. H01L 23/02

(52) U.S. Cl. 257/686

(57) ABSTRACT

A ball grid array package includes a substrate. A number of solder balls overlie the solder ball surface of the substrate. The solder balls are arranged within a ballout area. A chip is attached to the chip surface of the substrate by an adhesive layer. Contact pads of the chip are electrically connected to ones of the solder balls. The chip has an area that is smaller than the ballout area and the adhesive layer has an area that is at least as large as the ballout area such that each solder ball in the ballout area is located beneath the adhesive layer.

This application claims priority to German Patent Application 10 2004 029 587.5, which was filed Jun. 18, 2004, and is incorporated herein by reference.

### TECHNICAL FIELD

The invention relates to a substrate-based FBGA package with a substrate for receiving a chip, the chip being connected by an adhesive layer to the substrate, which is provided on the side facing away from the chip with solder balls, which are electrically connected to contact pads of the chip and in which the chip is enclosed by a molding compound.

### BACKGROUND

In particular, in the case of FBGA (Fine Ball Grid Array) packages, problems occur with respect to module reliability, in particular under exposure to changing temperatures. The reason for this can be seen in the different materials used and the resultant different coefficients of expansion, which, although reduced by appropriate material selection, cannot be eliminated. This causes thermally induced stresses between the individual components (chip, substrate, molding compound, solder balls), it being possible for the forces acting on individual solder balls to reach critical values, which may lead to crack formation or complete detachment of one or more solder balls. This would then result in the module being unusable.

Modules of this type contain a chip with at least one central row of bonding pads, the chip being mounted on a substrate by means of an adhesive. The substrate, for example a single-layer or multi-layer glass fiber laminate, is provided on the side facing away from the chip with solder balls, which are mounted on contacts on the substrate. These contacts are electrically connected by means of interconnects to bonding islands, which are arranged laterally next to a bonding channel in the substrate. The electrical connection of the bonding pads on the chip to the bonding islands on the substrate takes place by wire bridges, which are drawn through the bonding channel. This bonding channel is sealed with a sealing compound after the electrical connections have been established. Furthermore, the chip side is enclosed by a molding compound, which also covers the substrate in order to protect the back side and the sensitive chip edges. There is the possibility of enclosing the bonding channel and the chip simultaneously (one-step molding).

Substrate-based BGA packages of this type are usually constructed in such a way that the adhesive area provided for the chip mounting is aligned in a way corresponding to the chip size, in order to ensure secure attachment of the chip on the substrate. In this case, there are different versions with a slight adhesive set-back or projection with respect to the chip.

Because of the increasing number of contacts required, so-called fan-out packages, in which the ballout area, that is the area on which the solder balls are arranged, is much larger than the chip area, are increasingly being used. The result is that a greater number of solder balls are arranged outside the region of the chip and are consequently coupled by means of the substrate directly to the molding compound.

The result is that the solder balls located in the region of the chip are exposed to a different thermomechanical stress, in particular under changing temperatures, than those in the region of the molding compound.

### SUMMARY OF THE INVENTION

Embodiments of the invention provide a substrate-based FBGA package with improved reliability, in particular under exposure to changing temperatures, which can be produced at low cost.

For example, advantages can be achieved in the case of an FBGA package of the type mentioned at the beginning by the area of the adhesive layer on the substrate being made at least as large as the ballout area of the solder balls located on the side of the substrate that is facing away from the chip and by the chip being mounted centrally on the adhesive layer.

In a first refinement of the invention, the adhesive layer includes supporting balls located in the corners of the ballout area.

In a second refinement of the invention, the adhesive layer corresponds to the ballout area, individual adhesive pads being additionally arranged in the region of the respective supporting balls.

An elastomer with the property “low modulus adhesive” is used with preference as the adhesive layer.

Embodiments of the invention achieve the effect, in a surprisingly simple way, of decoupling the solder balls from the molding compound, because the thermomechanical stress is absorbed by utilizing the elasticity of the adhesive (low modulus adhesive) and consequently the forces acting on the solder balls, caused by the different coefficients of expansion of the materials used, are reduced. As a result, greater stability is achieved, in particular under exposure to changing temperatures, and consequently greater reliability of the module.

The invention allows the design of the adhesive area to be adapted in an ideal way to the requirements of the module or package with respect to module reliability.

The invention is to be explained in more detail below by an exemplary embodiment.

### DESCRIPTION OF THE DRAWINGS

For a more complete understanding of the present invention, and the advantages thereof reference is now made to the following descriptions taken in conjunction with the accompanying drawing, in which:

FIG. 1 shows a schematic representation of an FBGA package according to the prior art;

FIG. 2 shows an FBGA package provided with an adhesive area designed according to the invention;

FIG. 3 shows an FBGA package with an adhesive area of a particularly large surface area, which includes supporting balls located in the corners of the ballout; and

FIG. 4 shows an FBGA package with an adhesive area corresponding to FIG. 2 and additional adhesive pads over the supporting balls.

### THE FOLLOWING LIST OF REFERENCE SYMBOLS CAN BE USED IN CONJUNCTION WITH THE FIGURES

1 FBGA package
2 substrate
3 chip
4 adhesive layer
5 solder ball
6 bonding channel (filled with a sealing compound)
7 molding compound
8 ballout area
9 supporting ball
10 adhesive pad

### DETAILED DESCRIPTION OF ILLUSTRATIVE EMBODIMENTS

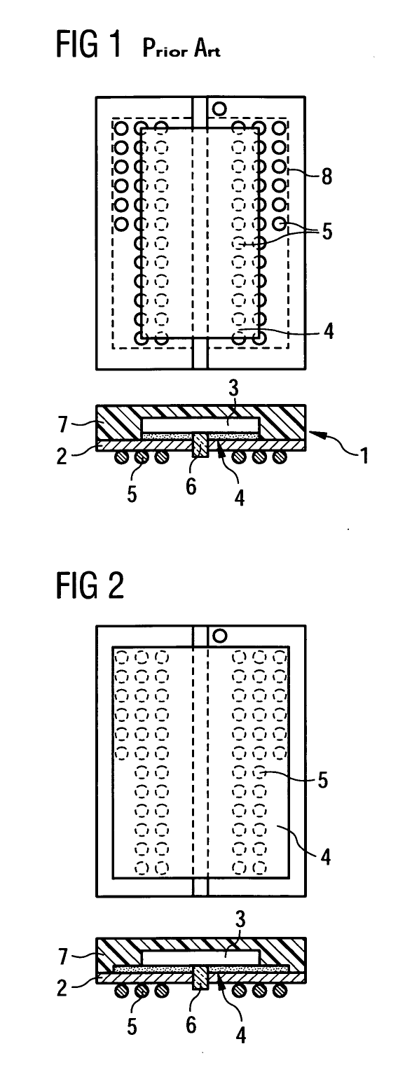

In FIG. 1, an FBGA package 1 according to the prior art is represented. This FBGA package 1 is constructed on a substrate 2, for example comprising a glass fiber laminate, by a chip 3 being attached on the substrate by means of an adhesive layer 4. The adhesive layer 4 may, in this case, have a slight adhesive set-back or adhesive projection with respect to the chip 3. The chip 3 is provided with at least one central row of bonding pads (not shown).

The substrate 2 may take the form of a single-layer or multi-layer glass fiber laminate, which is provided on the side facing away from the chip 3 with solder balls 5. The solder balls 5 are mounted on contacts on the substrate 2, which are electrically connected by means of interconnects to bonding islands, which are arranged laterally next to a bonding channel 6 which has been formed in the substrate 2. The electrical connection of the bonding pads on the chip 3 to the bonding islands on the substrate 2 takes place by wire bridges, which are drawn through the bonding channel 6. This bonding channel 6 is sealed with a sealing compound after the electrical connections have been established.

Furthermore, the chip 3 on the substrate 2 is enclosed by a molding compound 7, which also covers the substrate 2 in order to protect the back side of the chip 3 and its sensitive chip edges.

FIG. 1 graphically shows that the so-called ballout area 8 is much larger than the adhesive layer 4. This has the result that some solder balls 5 are located in the region of the adhesive layer 4 and some peripheral solder balls 5 are outside the adhesive layer 4 in the region of the molding compound 7.

According to a first embodiment of the invention, the area of the adhesive layer 4 is enlarged by being made to correspond at least to the ballout area 8, as is evident from FIG. 2. As a result, the direct thermally induced force coupling under exposure to changing temperatures from the molding compound 7 to the solder balls 5 of the outer row respectively is interrupted and the mechanical loading of the solder balls 5 is drastically reduced.

The adhesive layer 4 is preferably an elastomer (low modulus adhesive), which can absorb thermomechanical stress. This has the effect of reducing the forces acting on the solder balls, caused by the different coefficients of expansion of the mounting materials used. This leads to greater stability of the FBGA package 1, in particular under exposure to changing temperatures, in module reliability.

FIG. 3 shows a special package, in which additional supporting balls 9 are provided. The supporting balls 9 are intended to protect the other solder balls 5 against mechanical damage during the handling and provide additional stabilization after the mounting of the FBGA package 1 on a printed circuit board. The adhesive layer 4 here takes a two-dimensional form in such a way that the supporting balls 9 located in the corners are also included.

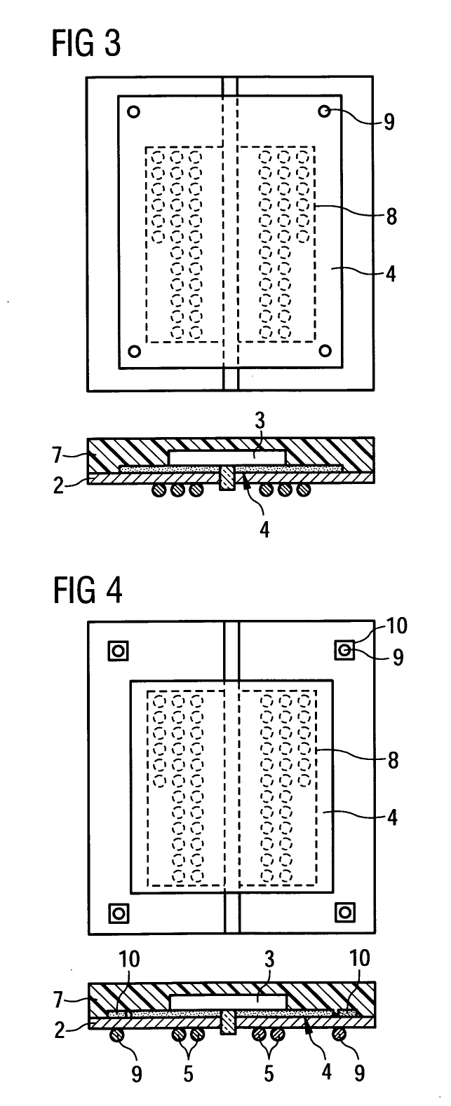

FIG. 4 shows another refinement. Here, the adhesive layer 4 is made larger than the ballout area 8, additional adhesive pads 10 being provided for the supporting balls 9.

In all the embodiments represented in FIGS. 2 to 4, there is an adhesive layer over each solder ball 5 and each supporting ball 9 on the chip side between the chip 3 or the molding compound 7 and the substrate 2. In other embodiments, which are not illustrated, the adhesive layer 4 may overlie some of the solder balls, e.g., only solder balls 5 and not supporting balls 9.

What is claimed is:

1. A substrate-based BGA package comprising:
a substrate including a chip surface and a solder ball surface opposite the chip surface;
a plurality of solder balls overlying the solder ball surface of the substrate, the solder balls being arranged within a ballout area; and
a chip being attached to the chip surface of the substrate by an adhesive layer, contact pads of the chip being electrically connected to ones of the solder balls, wherein the chip has an area that is smaller than the ballout area and wherein the adhesive layer has an area on the substrate that is at least as large as the ballout area such that each solder ball in the ballout area is located beneath the adhesive layer.

2. The substrate-based package of claim 1, further comprising supporting balls overlying the solder ball surface of the substrate, the supporting balls being located outside of the ballout area.

3. The substrate-based package of claim 2, wherein the area of the adhesive layer is larger than the ballout area such that each of the supporting balls are located beneath the adhesive layer.

4. The substrate-based package of claim 2, further including a plurality of individual adhesive pads attached to the chip surface of the substrate and arranged such that each individual adhesive pad overlies one of the supporting balls.

5. The substrate-based package of claim 4, wherein the area of the adhesive layer is about the same as the ballout area.

6. The substrate-based package of claim 1, wherein the area of the adhesive layer is about the same as the ballout area.

7. The substrate-based package of claim 1, wherein the adhesive layer comprises an elastomer.

8. The substrate-based package of claim 7, wherein the elastomer comprises a low modulus adhesive.

9. The substrate-based package of claim 1, wherein the package comprises an FBGA package.

10. The substrate-based package of claim 9, wherein the solder balls comprise microballs.

11. The substrate-based package of claim 1, wherein the chip is mounted centrally on the adhesive layer.

12. The substrate-based package of claim 1, further comprising a molding compound encapsulating the chip.

13. The substrate-based package of claim 1, wherein the substrate includes a bonding channel and wherein the contact pads of the chip are electrically connected to ones of the solder balls via wire bonds that extend from the contact pads of the chip, through the bonding channel and to bonding pads on the substrate, the bonding pads on the substrate being electrically coupled to the solder balls.

14. A substrate-based BGA package comprising:
a substrate for receiving a chip, the substrate including solder balls on a side of the substrate facing away from the chip, the solder balls being electrically connected to contact pads of the chip, wherein the chip is enclosed by a molding compound; and
an adhesive layer connecting the chip to the substrate, wherein the adhesive layer has an area on the substrate that is at least as large as a ballout area of the solder balls located on the side of the substrate that is facing away from the chip and wherein the chip is mounted centrally on the adhesive layer.

15. The substrate-based BGA package of claim 14, wherein the adhesive layer overlies supporting balls that are located in corners of the substrate.

16. The substrate-based BGA package of claim 14, wherein the substrate further includes supporting balls that are located in corners of the substrate, the substrate-based BGA package further comprising individual adhesive pads, each arranged in the region of a respective supporting ball.

17. The substrate-based BGA package of claim 14, wherein the adhesive layer comprises an elastomer.

18. The substrate-based BGA package of claim 17, wherein the elastomer is a low modulus adhesive.

19. The substrate-based BGA package of claim 11, wherein the BGA package comprises an FBGA package.

20. The substrate-based BGA package of claim 19, wherein the solder balls comprise microballs.
